(19) United States
(12) Patent Application Publication
(10) Pub. No.: US 2002/0185310 A1
(43) Pub. Date: Dec. 12, 2002

(54) Printed circuit board with resistive material for absorbing spurious modes

(76) Inventors: John J. Williamson, Herts (GB); Kalvin W. Korpela, Ottawa (CA); George V. Eleftheriades, Scarborough (CA)

Correspondence Address: William M. Lee, Jr., Lee, Mann, Smith, McWilliams, Sweeney & Ohlson, P.O. Box 2786, Chicago, IL, 60690-2786, US

(21) Appl. No.: 09/876,314

(22) Filed: Jun. 7, 2001

(51) Int. Cl. H05K 1/11; H01R 12/04

(52) U.S. Cl. 174/262

(57) ABSTRACT

Printed circuit boards with relatively high line speeds (for example, about one giga bit per second and above) are increasingly being developed. However, at these high line speeds problems arise with via-induced spurious modes being generated and propagating and reflecting along power or ground planes within the printed circuit board. This is problematic because any active devices which reference power or ground during the presence of such a spurious mode experience a change in the reference potential. This can lead to incorrect data reception or transmission. A resistive coating is applied to the edge of a printed circuit board, directly connected to the ground planes and capacitively connected to the power planes. This resistive coating acts to absorb spurious modes and prevent these from reflecting. In addition, the capacitive connection between the power planes and the resistive coating is enhanced, for example, using metallic flanges. This further improves absorption of spurious modes by the resistive coating.

### FIELD OF THE INVENTION

The present invention relates to a printed circuit board with resistive material for absorbing spurious modes and to a method of manufacture of the same. The invention is particularly related to, but in no way limited to, such printed circuit boards arranged to provide line rates at about 1 Gbps and above.

### BACKGROUND TO THE INVENTION

Printed circuit boards with relatively high line speeds (for example, about one giga bit per second and above) are increasingly being developed. However, at these high line speeds problems arise with spurious modes being generated and propagating along power or ground planes within the printed circuit board. This is problematic because any active devices which reference power or ground during the presence of such a spurious mode experience a change in the reference potential. This can lead to incorrect data reception or transmission. In addition, the spurious modes are often reflected within the power or ground planes and this can lead to a resonating effect. In this way the “noise” within the printed circuit board is compounded and the problems worsen.

Previously, it has been attempted to reduce the effects of such spurious modes by introducing additional components into the printed circuit board. However, this takes up valuable space on the printed circuit board and increases manufacturing complexity and expense.

In addition, it is extremely difficult to take into account the effects of such spurious modes when carrying out simulations of new printed circuit board designs. As a result, such simulations are difficult and not always successful, in which case it may be necessary to re-spin a newly designed printed circuit board at considerable expense.

An object of the present invention is to provide a printed circuit board with resistive material for absorbing spurious modes which overcomes or at least mitigates one or more of the problems noted above.

Further benefits and advantages of the invention will become apparent from a consideration of the following detailed description given with reference to the accompanying drawings, which specify and show preferred embodiments of the invention.

### SUMMARY OF THE INVENTION

According to a first aspect of the present invention there is provided a printed circuit board comprising:

a plurality of layers comprising electrically conducting and electrically insulating planes;

at least one via;

resistive material provided on at least part of one or more faces of the printed circuit board which are substantially perpendicular to the layers and wherein the resistive material is electrically connected to at least two of the electrically conducting planes.

This provides the advantage that the resistive material substantially absorbs spurious modes that propagate along the two electrically conducting planes. Because the spurious modes are substantially absorbed, they are prevented from reflecting and this stops the spurious modes from resonating and hence worsening. For example, the resistive material may be resistive ink sprayed onto the edge faces of a printed circuit board. (The edge faces being the four faces of the board which are not the primary or secondary faces.)

In a first embodiment the two or more electrically conducting layers are ground planes and said electrical connection is a direct connection between the resistive material and those ground planes. This enables spurious modes set up along those ground planes to be absorbed.

In a second embodiment the two or more electrically conducting layers are power planes and said electrical connection is a capacitive coupling between the resistive material and those power planes. In this case, spurious modes set up along the power planes are absorbed by the resistive material via the capacitive coupling.

In another embodiment one of the two or more electrically conducting layers is a ground plane and the other is a power plane. In this case the electrical connection between the ground plane and the resistive material is direct, and between the power plane and the resistive material the electrical connection is a capacitive coupling.

The via can be a through-hole via, a blind via or a buried via. A significant parasitic inductance is associated with such vias at relatively high line speeds and this causes the spurious modes to arise as described below. This occurs for any via, whether it be through-hole, blind vias or buried as described below.

Preferably the resistive material is covered with an electrically conducting shield such that in use, radiation from the printed circuit board is reduced and the effect of radiation from outside the printed circuit board on the printed circuit board is reduced.

Preferably, the resistance of the resistive material is arranged to substantially match the impedance of the two or more electrically conducting planes. This enables the spurious modes to be more effectively absorbed by the resistive material.

In another embodiment, the electrical connection comprises a capacitive coupling between the resistive material and at least one of the electrically conducting planes and the printed circuit board further comprises means for enhancing said capacitive coupling. For example, these means may comprise one or more electrically conducting flanges connected to the resistive material and extending towards the electrically conducting plane.

Preferably the flanges extend towards the electrically conducting plane, one on either side of the electrically conducting plane, and both extending beyond the end of the electrically conducting plane nearest the resistive material. This arrangement enables the capacitive coupling between the power plane and the resistive material to be increased.

The printed circuit board is preferably arranged to provide a line rate of at least 1 giga bit per second. This is advantageous because at such line rates, spurious modes are more likely to be generated and the need for the resistive material is increased.

According to another aspect of the present invention there is provided a method of manufacturing a printed circuit board comprising:

forming a plurality of layers supported on a substrate said layers comprising electrically conducting and electrically insulating planes;

forming at least one via through at least some of the layers;

applying resistive material to at least part of one or more faces of the printed circuit board which are substantially perpendicular to the layers; and

ensuring that the resistive material is electrically connected to at least two of the electrically conducting planes.

For example, the electrically conducting planes may be power planes or ground planes and the resistive material may be resistive ink that is sprayed onto the printed circuit board face.

Once the present invention is available to absorb spurious modes, the cost of modelling or simulating printed circuit boards which contain vias is significantly reduced. Spurious modes and their reflections are difficult to take account of in simulations and if the present invention is used, this problem is reduced.

The preferred features may be combined as appropriate, as would be apparent to a skilled person, and may be combined with any of the aspects of the invention.

### BRIEF DESCRIPTION OF THE DRAWINGS

In order to show how the invention may be carried into effect, embodiments of the invention are now described below by way of example only and with reference to the accompanying figures in which:

FIG. 1 is a schematic diagram of a cross-section through a printed circuit board according to the prior art;

FIG. 2 is a schematic diagram of a cross-section through a printed circuit board with resistive material applied to the edge faces;

FIG. 3 is a schematic circuit diagram representing the function of components in a prior art printed circuit board;

FIG. 4 is a schematic circuit diagram representing the function of components in a printed circuit board with resistive material applied to the edge faces;

FIG. 5 is a graph of voltage against time for simulation results for the circuits of FIGS. 3 and 4.

### DETAILED DESCRIPTION OF INVENTION

Embodiments of the present invention are described below by way of example only. These examples represent the best ways of putting the invention into practice that are currently known to the Applicant although they are not the only ways in which this could be achieved.

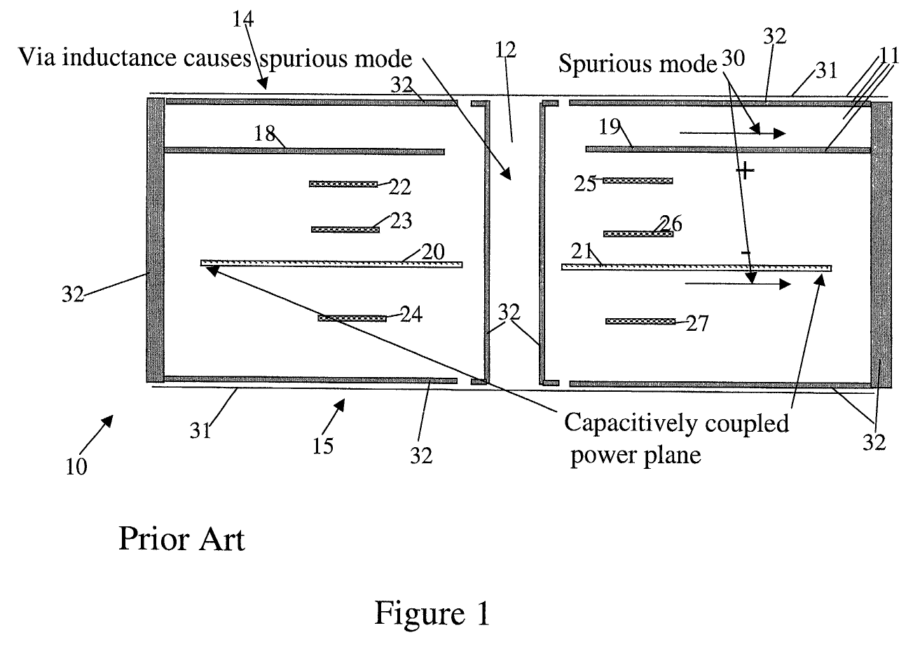

FIG. 1 is a schematic diagram of a cross-section through a printed circuit board according to the prior art. The printed circuit board 10 comprises a plurality of layers of material 11 built up upon one another as is known in the art, with regions of some conducting layers being absent in order that electrical connections may be formed and components supported by or within the layered structure.

The printed circuit board comprises one or more vias and the example in FIG. 1 shows a through-hole via 12. A via is an aperture extending through at least part of a printed circuit board in a direction substantially orthogonal to the planes of the layers of the printed circuit board. The via usually pierces the power and ground planes with a non-conductive space between these reference planes and the via and is used, for example, to transfer a signal from one layer to another within the printed circuit board.

Other types of vias, such as blind vias, where the aperture extends from one surface of the printed circuit board and terminates within the printed circuit board can be used. Alternatively, buried vias can be used, which originate and terminate within the printed circuit board and so are not visible from the outside of the structure.

In the example shown in FIG. 1, the edge faces of the printed circuit board are coated with an electrically conducting shield 32, such as a metallic shield. This shield is at ground potential and acts to prevent radiation from being emitted from the printed circuit board and also to shield the printed circuit board from external radiation. The upper surface of the printed circuit board 14, referred to as the primary surface, and the lower surface of the printed circuit board 15, referred to as the secondary surface, both also have a shield 32 of electrically conducting material at ground potential. These surfaces typically also have an outer solder resist layer 31 comprising insulating material such as plastics material to protect the printed circuit board.

The printed circuit board comprises one or more ground planes 18, 19 (where 18 and 19 are part of the same plane) and one or more power planes 20, 21 (where 20 and 21 are part of the same plane) as well as signal planes 22, 23, 24, 25, 26, 27 (where planes 25, 26 and 27 are the same planes as 22, 23 and 24 respectively). Consider the situation when a signal from signal plane 24 passes into the via 12, along the via and into signal plane 25. A parasitic inductance is associated with the via 12. For example, in the situation shown in FIG. 1, the via parasitic inductance can easily be of the order of 0.5 to 1.0 nH (nano Henry). When the signal, which is a time varying current (exceeding 1 GHz frequency, for example), passes through the via which has the parasitic inductance, a voltage is created across the inductance. This voltage is able to couple into nearby power and or ground planes and then to propagate along those planes as a spurious mode. In the example of FIG. 1, a spurious mode 30 is shown propagating along ground plane 19 and power plane 21. The voltage created across the inductance is indicated in FIG. 1 by the + and − signs which are intended to indicate that the ground plane 19 has a positive potential compared to the power plane 21.

The spurious mode propagates along the ground and power planes 19, 21 and may be reflected and return along those planes. In this way the spurious modes form standing waves and resonance effects occur which act to amplify the noise within the printed circuit board.

Any active devices (such as digital integrated transmitters and receivers) connected to the printed circuit board and which reference the power or ground planes 21, 19 during the presence of spurious modes experience a change in reference potential. This can lead to incorrect data reception or transmission. This is a particular problem when standing waves and resonance occur which exacerbate the spurious mode effects.

In the example shown in FIG. 1 the spurious mode is set up between a ground plane 19 and a power plane 21. However, such spurious modes may also be set up between pairs of power planes or pairs of ground planes.

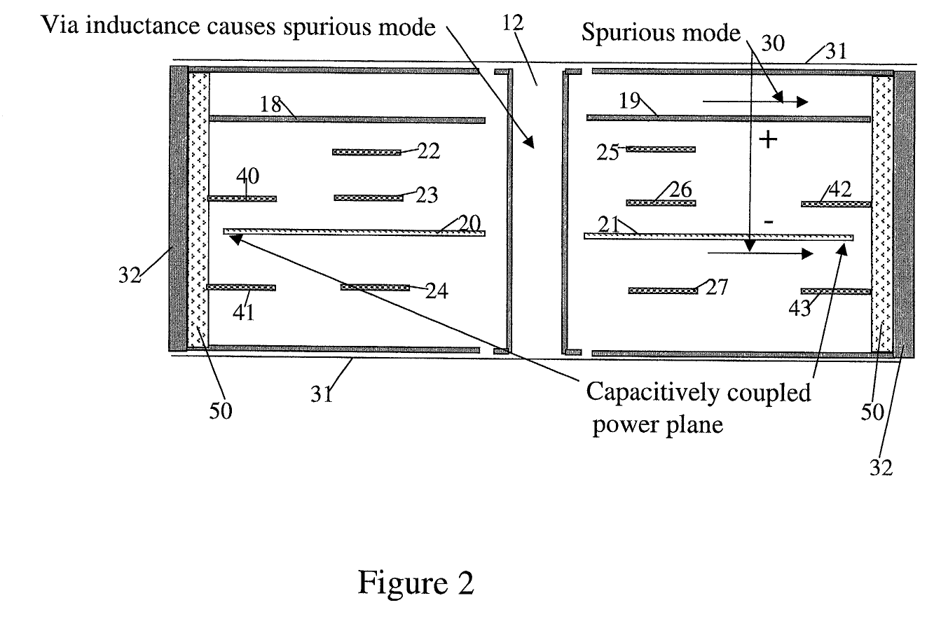

FIG. 2 shows the printed circuit board of FIG. 1 that has been modified to comprise resistive material 50 on the edge faces. In this example, the edge faces are coated with resistive material, which may be a resistive ink that is sprayed onto those faces during the manufacturing process. The metallic shield 32 is then applied on the outer surface of the resistive material 50. However, it is not essential for the edge faces to be fully coated with resistive material 50. Only some regions of the edge faces need to be covered in resistive material 50 such that the ground planes 18, 19 and power planes 20, 21 are electrically connected to the resistive material 50. Any suitable resistive material may be used to enable these electrical connections to be achieved.

The term “edge faces” is used to refer to those faces of the printed circuit board which are substantially perpendicular to the layers 11. If the printed circuit board is thought of as having six faces, then there are four edge faces a primary surface 14 and a secondary surface 15.

The electrical connections between the ground planes 18, 19 and the resistive material 50 are direct as indicated in FIG. 2. That is the ground planes 18, 19 physically touch the resistive material 50. However, the electrical connections between the power planes 20, 21 and the resistive material 50 are capacitive. That is, the power planes 20, 21 do not physically touch the resistive material 50. The strength of the capacitive connection between the power planes and the resistive material 50 increases as the gap between the power planes and the resistive material reduces.

In one embodiment means is provided to enhance or increase the strength of the capacitive connection between the power planes 20, 21 and the resistive material 50. Any suitable means may be used, for example, electrically conducting flanges 40, 41, 42, 43 may be provided, extending from the resistive material towards the power planes 20, 21. These flanges may be formed from any suitable electrically conducting material such as metal. In the example shown in FIG. 2, a pair of flanges 40, 41 are positioned one on either side of a power plane 20 and extend towards the power plane. Preferably, both flanges extend beyond the end of the power plane 20 nearest the resistive material 50 or in other words, overlap at least part of the power plane 20. The flanges act to enhance the strength of the capacitive connection between the power plane 20 and the resistive material 50. Thus it would also be possible to use only one flange 40 or to use other shapes of flange and position these in other ways as is apparent to a skilled person in the art. The flanges are constructed during the lamination process in which the printed circuit board is built up.

The resistive material 50 is preferably arranged to provide a resistance of a similar order to that of the impedance of the two electrically conducting planes between which spurious modes may be set up. An estimate is made of the characteristic impedance of these electrically conducting planes, or reference planes. For example, this estimate is likely to be within the 2 to 20 Ohm range. The resistive material 50 is then applied such that it provides a resistance at the edge of the printed circuit board of a similar order to (or which substantially matches) that of the characteristic impedance of the reference planes.

It is not essential for the resistive material to be applied such that it gives a uniform resistance. For example, a region of the resistive material in the neighbourhood of a particular pair of reference planes may be different from another region of resistive material associated with different reference planes.

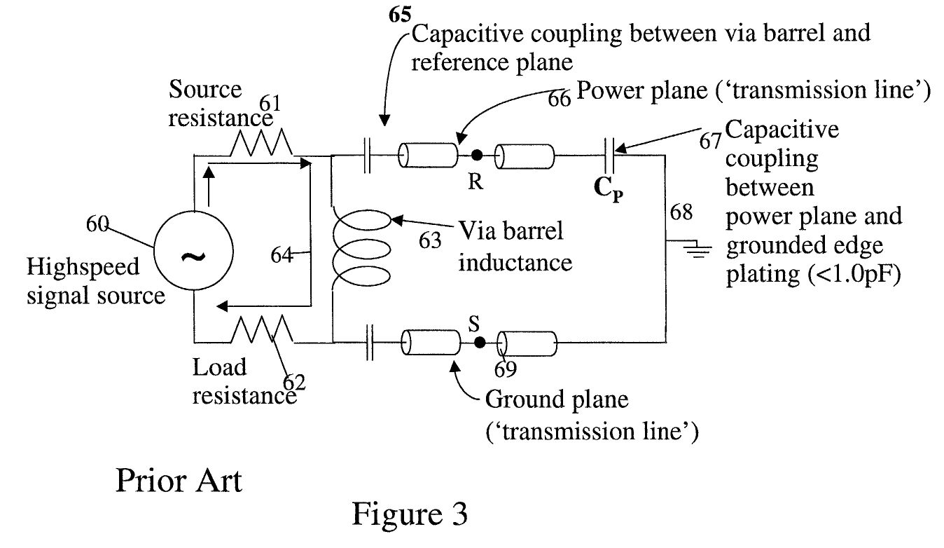

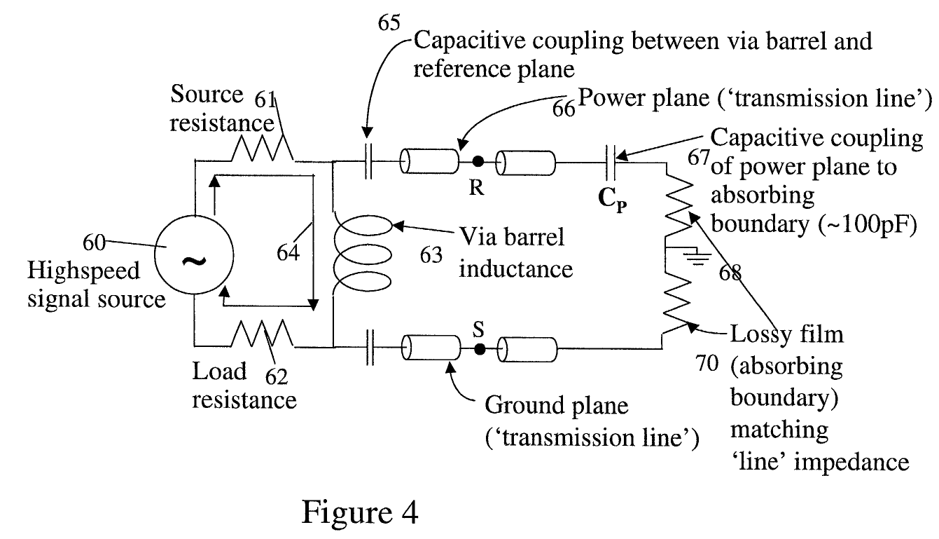

The resistive material 50 act as an absorbing boundary which absorbs spurious modes. This prevents spurious standing waves from being set up because the spurious modes are absorbed and prevented from reflecting back along the power or ground planes. This reduces the noise associated with spurious modes. FIGS. 3 and 4 are schematic circuit diagrams representing the function of components in the prior art printed circuit board of FIG. 1 and the new printed circuit board of FIG. 2.

FIG. 3 shows the prior art situation where a high speed signal source 60 sends a signal along a signal path 64, via a source resistance 61, a via which has an inductance 63 and a load resistance 62. The via is capacitively coupled 65 to a pair of reference planes, a power plane 66 and a ground plane 69 in this example. The ground plane is directly connected to grounded edge plating 68 on the printed circuit board. However, the power plane 66 is capacitively coupled 67 to the grounded edge plating 68. This capacitive coupling is represented as C_{P} in FIGS. 3 and 4. In the event that low frequency spurious modes or components are generated between the power and ground planes, then C_{P} provides a near-open circuit which causes any spurious modes to be reflected. In the event that high frequency spurious modes are generated between the power and ground planes, then C_{P} is a near-short, also causing the spurious modes to be reflected. FIG. 4 indicates how the present invention prevents such reflections from occurring.

Previously, in order to reduce the noise associated with spurious modes, others have used additional decoupling capacitors and/or more vias between the ground plane 69 and the power plane 66. However, such additional capacitors or vias take up valuable space within the printed circuit board and add to manufacturing complexity and expense.

FIG. 4 is the same as FIG. 3 except that resistances 70 are shown connected between the power 66 and ground 69 planes and the grounded edge plating 68. These resistances are provided by the resistive material 50 which act as a lossy film or absorbing boundary arranged to approximately match the impedance of the power and ground planes. In addition, the value of C_{P} is significantly increased as compared with the prior art situation of FIG. 3, for example, by providing metallic flanges as indicated in FIG. 2. In FIG. 3 the value of C_{P} is about 0.5 nF (nano Farads) or less and in FIG. 4 the value of C_{P} is about 100 nF. Thus in the embodiment of FIG. 4, C_{P} is a near-short for all significant spurious frequency components. However, the lossy film 70 provides a “matched” termination which eliminates most of the spurious mode reflections.

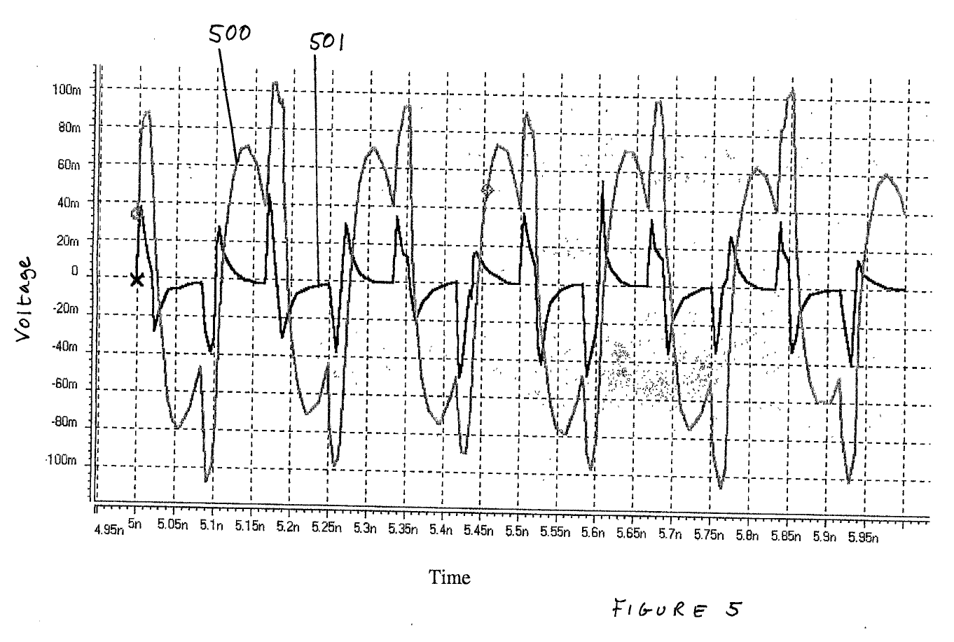

FIG. 5 is a graph of voltage against time for a simulated spurious mode signal in the circuits of FIGS. 3 and 4. The y-axis represents voltage between the power and ground planes midway between the driver and the absorbing boundary (i.e. between points R and S in either FIG. 3 or FIG. 4) in units of mV. The x-axis represents time in nano seconds. Line 500 shows the simulation results for the prior art situation in which no resistive material 50 is used and in which C_{P} is less than 1.0 pico-Farads. Line 501 shows the simulation results for the situation in which resistive material 50 is used to provide an effective resistance of 3.5 Ohms at the edge of the printed circuit board and where C_{P} is 100 pico-Farads. It can be seen that the spurious mode signal of the prior art situation (line 500) has a much larger amplitude than that when the arrangements of the present invention are used (line 501).

Any range or device value given herein may be extended or altered without losing the effect sought, as will be apparent to the skilled person for an understanding of the teachings herein

A range of applications are within the scope of the invention. These include situations in which it is required to reduce the effects of spurious modes within printed circuit boards, especially where the printed circuit boards are arranged to provide line speeds of around 1 giga bit per second and above.

1. A printed circuit board comprising:
(i) a plurality of layers comprising electrically conducting and electrically insulating planes;
(ii) at least one via;
(iii) resistive material provided on at least part of one or more faces of the printed circuit board which are substantially perpendicular to the layers and wherein the resistive material is electrically connected to at least two of the electrically conducting planes.

2. A printed circuit board as claimed in claim 1 wherein the resistive material is arranged such that in use it substantially absorbs spurious modes travelling along the at least two electrically conducting planes.

3. A printed circuit board as claimed in claim 1 wherein the at least two electrically conducting layers are ground planes and said electrical connection is a direct connection between the resistive material and those ground planes.

4. A printed circuit board as claimed in claim 1 wherein the at least two electrically conducting layers are power planes and said electrical connection is a capacitive coupling between the resistive material and those power planes.

5. A printed circuit board as claimed in claim 1 wherein one of the at least two electrically conducting layers is a ground plane and the other is a power plane and wherein said electrical connection between the ground plane and the resistive material is direct, and between the power plane and the resistive material is a capacitive coupling.

6. A printed circuit board as claimed in claim 1 wherein said via is selected from a through-hole via, a blind via or a buried via.

7. A printed circuit board as claimed in claim 1 wherein said resistive material is covered with a metallic shield such that in use, radiation from the printed circuit board is reduced and the effect of radiation outside the printed circuit board on the printed circuit board is reduced.

8. A printed circuit board as claimed in claim 1 wherein said resistive material is arranged to substantially reduce reflection of spurious modes travelling within the at least two electrically conducting planes.

9. A printed circuit board as claimed in claim 1 wherein the resistance of the resistive material is arranged to substantially match the impedance of the at least two electrically conducting planes.

10. A printed circuit board as claimed in claim 1 wherein said electrical connection comprises a capacitive coupling between the resistive material and at least one of the electrically conducting planes and wherein said printed circuit board further comprises means for enhancing said capacitive coupling.

11. A printed circuit board as claimed in claim 10 wherein said means for enhancing said capacitive coupling comprises one or more electrically conducting flanges connected to the resistive material and extending towards the electrically conducting plane.

12. A printed circuit board as claimed in claim 10 wherein said means for enhancing said capacitive coupling comprises two electrically conducting flanges connected to the resistive material and extending towards the electrically conducting plane, one on either side of the electrically conducting plane, and both extending beyond the end of the electrically conducting plane nearest the resistive material.

13. A printed circuit board as claimed in claim 1 which is arranged to provide a line rate of at least 1 giga bit per second.

14. A method of manufacturing a printed circuit board comprising:
(i) forming a plurality of layers supported on a substrate said layers comprising electrically conducting and electrically insulating planes;
(ii) forming at least one via through at least some of the layers;
(iii) applying resistive material to at least part of one or more faces of the printed circuit board which are substantially perpendicular to the layers; and
(iv) ensuring that the resistive material is electrically connected to at least two of the electrically conducting planes.
